(19) United States
(12) Patent Application Publication
(10) Pub. No.: US 2012/0314373 A1
(43) Pub. Date: Dec. 13, 2012

(54) Seabed Pressure Bottle Thermal Management

(76) Inventor: Brian Park, Austin, TX (US)

(21) Appl. No.: 13/576,399

(22) PCT Filed: Feb. 11, 2011
(86) PCT No.: PCT/US2011/000258

§ 371 Date: Aug. 1, 2012

Related U.S. Application Data
(60) Provisional application No. 61/337,685, filed on Feb. 11, 2010.

(51) Int. Cl. H05K 7/20; B23P 6/00

(52) U.S. Cl. 361/715; 29/890.031

(57) ABSTRACT

A subsea electronics module or pressure bottle with greatly enhanced capabilities for conducting heat away from internal electronics boards by means of an adjustable heat conduction wedge system.

### CROSS REFERENCE TO RELATED APPLICATIONS

This application claims the benefit of U.S. provisional Ser. No. 61/337,685 filed Feb. 11, 2010.

### BACKGROUND AND FIELD OF THE DISCLOSURE FIELD

The field relates to subsea pressure bottles used to house electronic assemblies and to the thermal problems associated with them.

### BACKGROUND

Various aspects of the control of underwater fluid extraction wells, for example subsea hydrocarbon production wells, are managed by monitoring systems housed in a cylindrical pressure bottle. These systems may include opto-electronics and/or optical sensing systems. This may be called a subsea electronics module, a pressure bottle, or other terms. Existing pressure bottles contain a number of printed wiring boards that perform a number of dedicated functions. The exterior of the pressure bottle is typically a metal cylinder of circular cross-section designed to handle the substantial pressure of the environment. This houses control printed circuit electronic boards, located on connectors mounted on a motherboard, which facilitates connections to input and output connectors at the end of the module as well as the feeding of power within the module.

The electronic components within such pressure bottles generate heat and that heat must be removed to prevent damage from overheating. Radiant heat transfer is not very effective in such an application and moving parts such as fans are not allowed for reliability reasons. This leaves heat conduction as a preferred alternative. Clamps that create a thermal pathway from electronic circuit boards and the exterior shell of the pressure bottle are often used but provide a rather limited surface area for heat transfer.

U.S. Pat. No. 4,400,858 to Goiffon, et al describes a down hole electronics package of a MWD telemetry system in which clips are used to engage the inner periphery of the tube surrounding the electronics. The clips are made from a resilient material and have an outer radii of curvature that are slightly larger than the inner radius of the tube so that when the clip is inserted into the tube it is distorted to grip the tube and transfer heat to the tube wall. This facilitates heat conduction to the outer wall of the enclosure but to a limited extent, particularly with high heat generation electronic circuits.

There are other prior art examples in U.S. Pat. Nos. 6,865,085; 5,382,175, 4,547,833; 4,546,407; and 4,184,539—all of which use rather limited conduction or some combination with radiation to affect heat transfer.

There is a need then for a more robust solution for heat removal in these submerged electronic bottles. One that does not involve convection or radiation, which are usually not options in this application.

### BRIEF SUMMARY OF THE DISCLOSURE

This need is met as described in this disclosure.

It can be met by a subsea electronics module or pressure bottle with greatly enhanced capabilities for conducting heat away from internal electronics boards including at least: an external housing with a substantially circular cross-section and a length L; at least one electronics mounting plate; electronic components mounted on the at least one electronics mounting plate; at least one adjustable wedge extending along length L and positioned between the at least one electronics mounting plate the external housing wall; wherein the at least one adjustable wedge extending along length L and positioned between the at least one electronics mounting plate and the external housing wall has an adjusting mechanism for pressing the adjustable wedge outwardly against the interior of the external housing to increase the heat conduction contact area.

In another aspect this need is met when the at least one adjustable wedge extending along length L and positioned between the at least one electronics mounting plate and the external housing wall is configured as a uniform wedge with a wedge angle and the electronics mounting plate has an opposite wedge shape with identical wedge angle.

In another aspect this need is met when the at least one adjustable wedge extending along length L and positioned between the at least one electronics mounting plate and the external housing wall is configured as a saw-toothed wedge.

In another aspect this need is filled by a method for increasing heat conduction between electronic boards and the exterior housing wall in a subsea electronics module or pressure bottle of length L comprising the steps of: placing at least one adjustable wedge extending along length L and positioned between the at least one electronics mounting plate the external housing wall; providing an adjusting mechanism for pressing the adjustable wedge outwardly against the interior of the external housing to increase the heat conduction contact area.

In another aspect this need is filled by when the step of providing an adjusting mechanism for pressing the adjustable wedge outwardly against the interior of the external housing is provided by a screw mechanism for moving the at least one adjustable wedge along length L.

### BRIEF DESCRIPTION OF THE SEVERAL VIEWS OF THE DRAWINGS

Preferred embodiments and their advantages are best understood by reference to FIGS. 1 through 8.

FIG. 1 illustrates a sub sea pressure bottle with internal circuit boards and illustrates a wedge heat conductor.

FIG. 2 is a cut-away showing the relationship of wedges to an electronic mounting plate.

FIG. 3 is an illustration of the thermal profile of a pressure bottle interior without use of wedges.

FIG. 4 is an illustration of the thermal profile of a pressure bottle interior with the use wedges.

FIG. 5 is an illustration of the workings of a wedge.

FIG. 6 is an illustration of a saw-toothed wedge.

FIG. 7 is an illustration of the use of multiple wedges.

FIG. 8 is an illustration of the use of multiple wedges with multiple shelves in a pressure bottle.

### DETAILED DESCRIPTION

Although certain embodiments of the present disclosure and their advantages have been described herein in detail, it should be understood that various changes, substitutions and alterations can be made without departing from the spirit and scope of the invention as defined by the appended claims. Moreover, the scope is not intended to be limited to the particular embodiments of the processes, machines, manufactures, means, methods and steps described herein. As a person of ordinary skill in the art will readily appreciate from this disclosure, other processes, machines, manufactures, means, methods, or steps, presently existing or later to be developed that perform substantially the same function or achieve substantially the same result as the corresponding embodiments described herein may be utilized.

Accordingly, the appended claims are intended to include within their scope such processes, machines, manufactures, means, methods or steps.

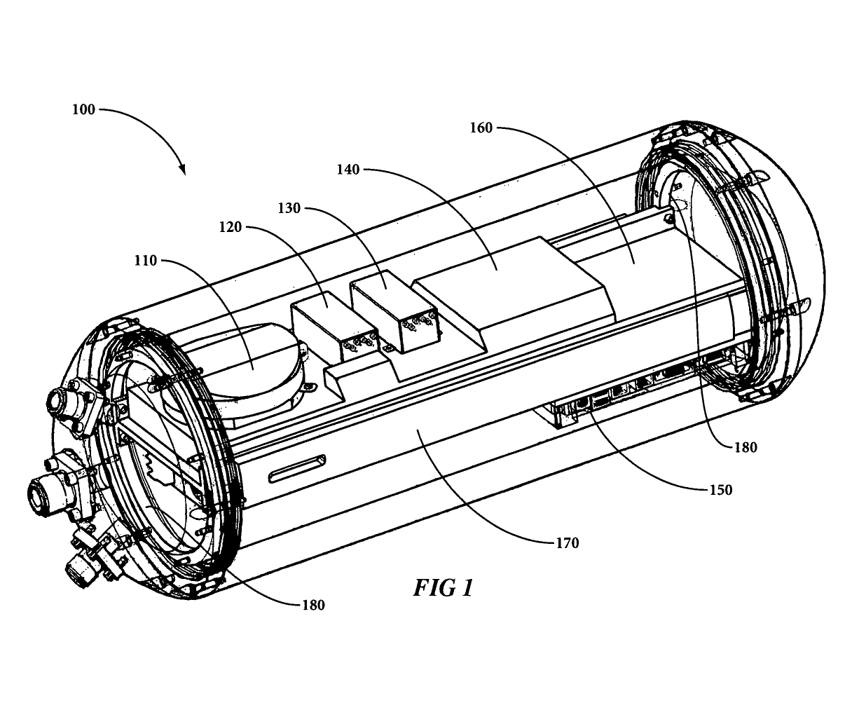

FIG. 1, shown as the numeral 100, is a rendering of a pressure bottle showing a number of electronic components 110, 120, 130, 140, and a single board computer system 150. The exterior pressure bottle itself is shown as transparent for illustrative purposes but is usually made from a stainless steel or beryllium copper metal. The electronics are usually mounted in aluminum enclosures with fingers in them that contact the hot spots on the boards. This spreads the heat and moves it to the main mounting plate 160. The enclosures also retain connectors and provide precise paths for cables so that they are completely constrained. To facilitate conduction heat transfer most prior art implementations have clips, clamps, or ring mechanisms near the ends of the mounting plate, such as 180 in FIG. 1. One possible embodiment is shown as 170 in FIG. 1—an extended wedge that runs the length of the pressure bottle and can be adjustably pressed against the wall of the pressure bottle to provide a greatly increased heat conduction area.

There is a thin flexible thermal gasket or thermal grease between the wedges and the bottle wall to compensate for compression of the bottle under pressure, so the wedge is not tightened completely against the bottle—the bottle is free to expand and contract as required. In an example case the wedge increases the contact area from 2.3 sq. in. to 55.9 sq. in. and thus distributes the heat more evenly to the wall.

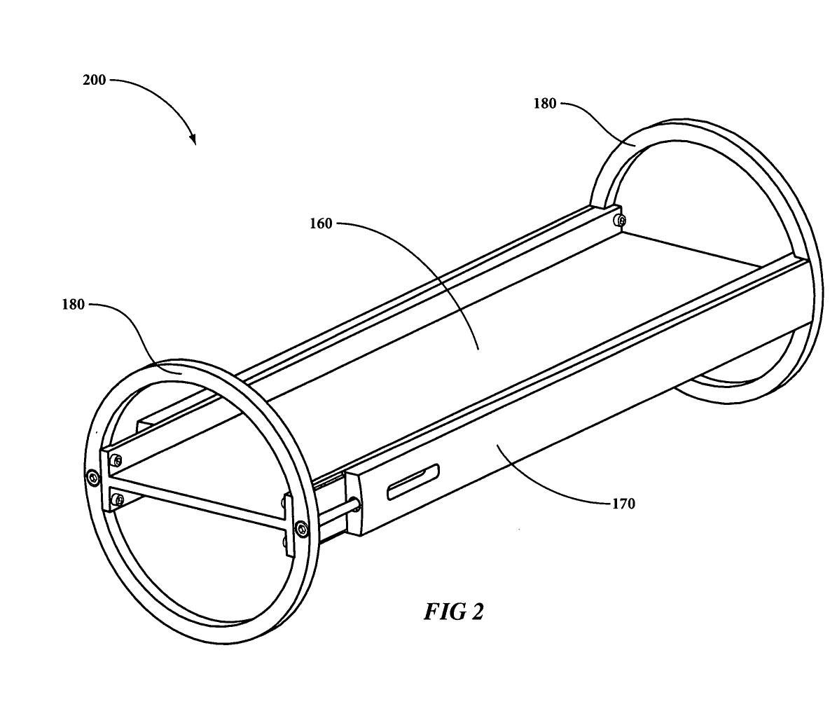

FIG. 2, shown generally as 200, is a stripped down version of FIG. 1, showing only the main mounting plate 160, the mounting rings 180, and the adjustable wedge 170—the adjustable wedge being one of the possible embodiment. An identical adjustable wedge is provided on the opposite side of the pressure bottle.

To quantify the potential improvement from this dramatic increase of heat transfer surface area a thermal model of the bottle shown in FIG. 1 was developed and simulated for two cases—first for a case in which an adjustable wedge was not included and a second case in which the adjustable wedge was included and pressed against the exterior wall.

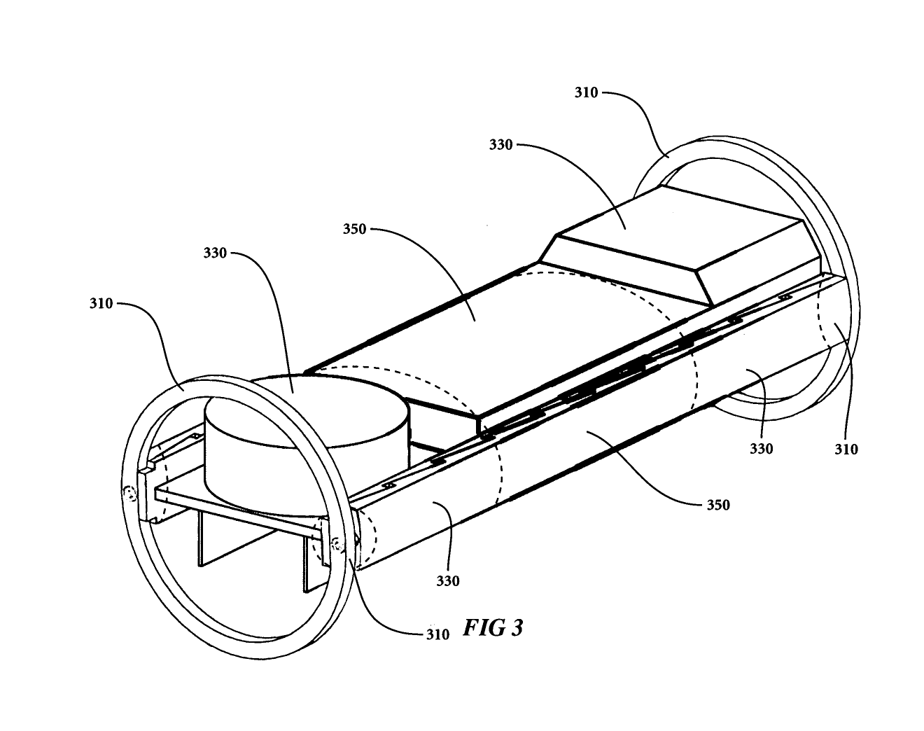

FIG. 3 demonstrates the thermal gradients for a first case in which the available heat transfer area is provided by the mounting rings 310 only. For typical heat generated by electronic components the resultant temperature distribution resulted in most of the center components 350 eight degrees Celsius hotter than end rings 310. Regions 330 were about 4 degrees hotter than end rings 310.

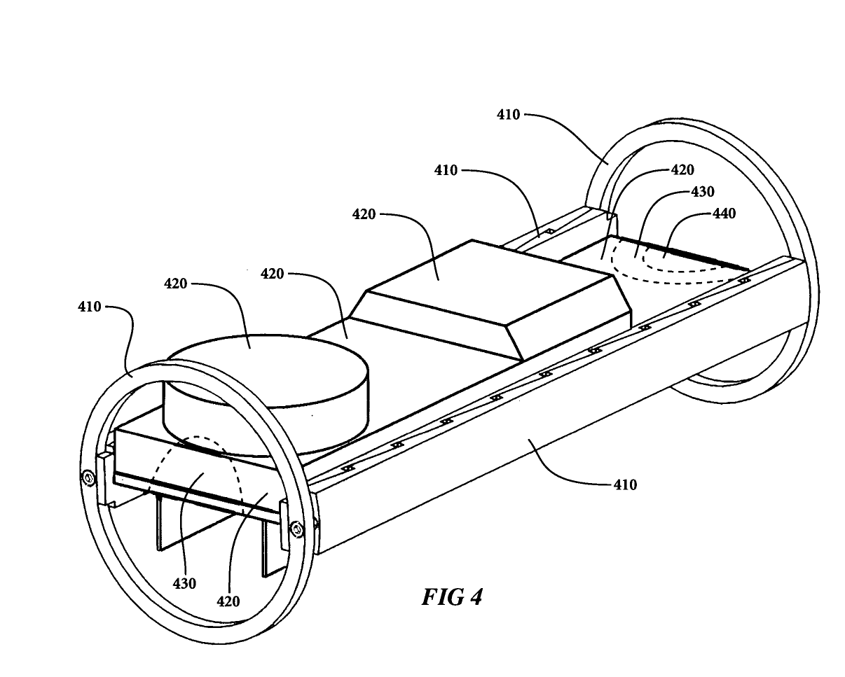

FIG. 4 demonstrates the thermal gradient for a second case in which an adjustable wedge 410 is used and is in full contact with the exterior wall. The resulting temperature for this case, using the same parameters of heat generated results in components 410 all in contact with the exterior wall being within 0.2 degrees Celsius of each other. Regions 420 were within 0.5 degrees Celsius of regions 410. Regions 430 were one degree hotter than regions 410 and region 440 the hottest at 1.5 degrees Celsius hotter than region 410.

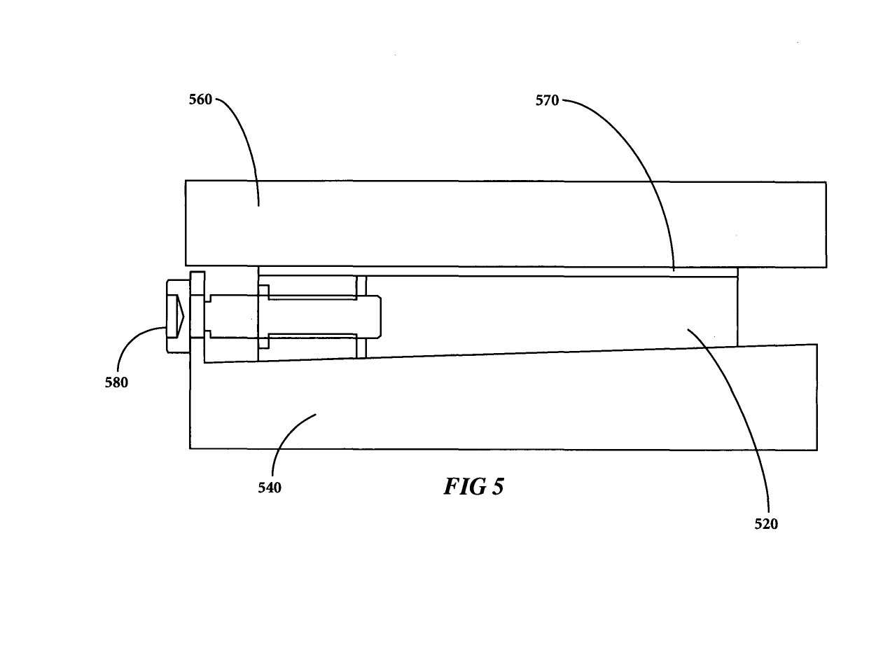

FIG. 5 illustrates then manner in which an adjustable wedge 520 is used to maintain good contact between the electronics housing 540 and the outer housing 560. The electronics housing 540 and the wedge 520 are both wedge shaped but in opposite directions and with the same wedge angle θ. Thus as screw 580 is turned the amount of vertical movement a is dependent on the wedge angle θ, the thread pitch β of screw 580, and the number of turns N of the screw so that α=N*β*Tan θ. With such a design the contact with the outer housing 560 as exemplified by the thickness of the illustrated thermal grease 570 is uniform along the length of the wedge, insuring uniform contact for uniform heat conduction.

With single wedges, the angle depends on the length of the cylinder and the space available between the outer housing and the electronics housing. The longer the housing, the shallower the angle, so it takes more turns to tighten the wedge.

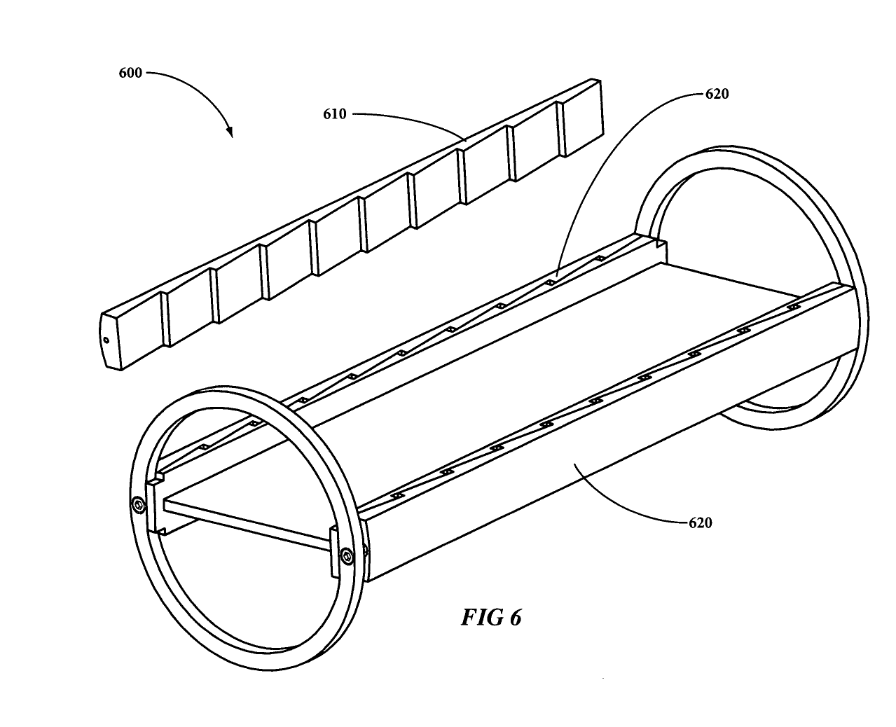

In another embodiment of the inventive concept FIG. 6 illustrates an implementation that uses multiple sloped surfaces rather than one long one such as in FIG. 2. The result is a saw toothed wedge 610. The saw toothed wedge installed inside a pressure bottle is shown as 620 on either side of the bottle. The saw tooth arrangement enables a simpler functionality for expanding the wedge. With saw tooth wedges the angle can be much steeper, so fewer turns are required, and the angle is independent of the length. A small forward adjustment of a screw on one end of the bottle provides a sideways movement of the wedge. This allows for the wedge to be independent of the length of the enclosure, so the angle can be fixed at a much greater value. One turn of the screw provides more lateral movement for less linear movement. The surface area of thermal contact is maintained. The saw tooth wedge will work with any length of bottle.

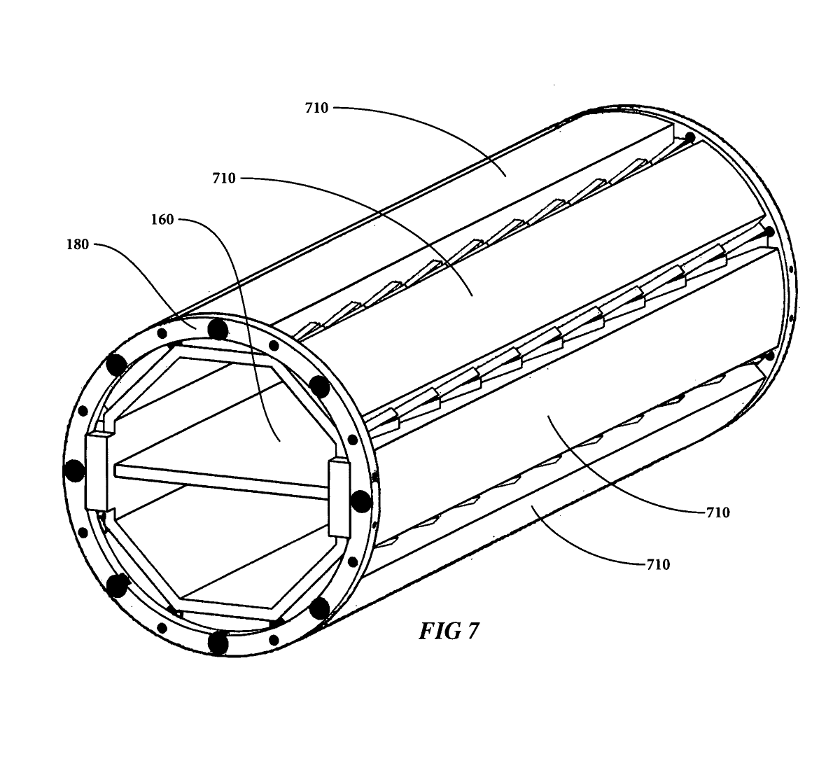

In more demanding applications in which more heat conduction area is required alternate embodiments that include more wedge lobes deployed radially around the pressure bottle. FIG. 7 illustrates an ultimate approach to this embodiment with an octagonal saw tooth wedge cylinder. A total of eight wedges 710 surround the electronic shelf. This type of arrangement can result in 4 times the contact area of the two-wedge unit of FIG. 2.

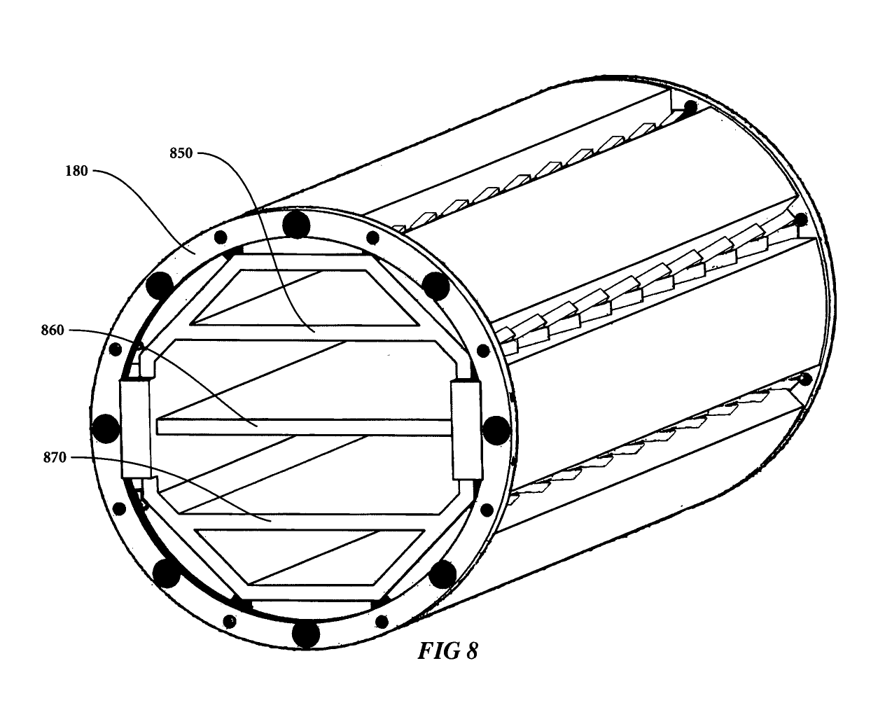

With such expanded heat conduction area the possibility of adding shelves for multiple tiers of electronics is now possible. FIG. 8 illustrates another octagonal saw tooth wedge cylinder with multiple shelves 850, 860, 870. All internal surfaces can be used for mounting electronics. This arrangement would be assembled layer by layer and the saw tooth housing added last, with thermal gasket material or thermal grease in between to enhance conduction.

In practice any of the embodiments illustrated in FIGS. 2, 6, 7. and 8 can be inserted in the subsea pressure bottle and after insertion the end screws on each of the wedges can then be tightened to outwardly press the wedge against the interior wall of the external housing.

All of the methods disclosed and claimed herein may be executed without undue experimentation in light of the present disclosure. While the disclosure may have been described in terms of preferred embodiments, it will be apparent to those of ordinary skill in the art that variations may be applied to the components described herein without departing from the concept, spirit and scope of the disclosure. All such similar substitutes and modifications apparent to those skilled in the art are deemed to be within the spirit, scope, and concept of the invention as defined by the appended claims.

1. A subsea electronics module or pressure bottle with greatly enhanced capabilities for conducting heat away from internal electronics boards comprising:
a. an external housing with a substantially circular cross-section and a length L;
b. at least one electronics mounting plate;
c. electronic components mounted on said at least one electronics mounting plate;
d. at least one adjustable wedge extending along length L and positioned between said at least one electronics mounting plate said external housing wall;
e. wherein said at least one adjustable wedge extending along length L and positioned between said at least one electronics mounting plate and said external housing wall has an adjusting mechanism for pressing said adjustable wedge outwardly against the interior of said external housing to increase the heat conduction contact area.

2. The subsea electronics module or pressure bottle with greatly enhanced capabilities for conducting heat away from internal electronics boards of claim 1 wherein said at least one adjustable wedge extending along length L and positioned between said at least one electronics mounting plate and said external housing wall is configured as a uniform wedge with a wedge angle and said electronics mounting plate has an opposite wedge shape with identical wedge angle.

3. The subsea electronics module or pressure bottle with greatly enhanced capabilities for conducting heat away from internal electronics boards of claim 1 wherein the at least one adjustable wedge extending along length L and positioned between said at least one electronics mounting plate and said external housing wall is configured as a saw-toothed wedge.

4. A method for increasing heat conduction between electronic boards and the exterior housing wall in a subsea electronics module or pressure bottle of length L comprising the steps of:
a. placing at least one adjustable wedge extending along length L and positioned between said at least one electronics mounting plate said external housing wall;
b. providing an adjusting mechanism for pressing said adjustable wedge outwardly against the interior of said external housing to increase the heat conduction contact area.

5. The method for increasing heat conduction between electronic boards and the exterior housing wall in a subsea electronics module or pressure bottle of length L of claim 4 wherein said step of providing an adjusting mechanism for pressing said adjustable wedge outwardly against the interior of said external housing is provided by a screw mechanism for moving said at least one adjustable wedge along length L.
